(19) United States
(12) Patent Application Publication
(10) Pub. No.: US 2022/0384206 A1
(43) Pub. Date: Dec. 1, 2022

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Shinya Sasaki, Toyama (JP); Noriaki Michita, Toyama (JP); Katsuhiko Yamamoto, Toyama (JP); Takashi Nakagawa, Toyama (JP); Kazuhiro Yuasa, Toyama (JP)

(73) Assignee: KOKUSAI ELECTRIC CORPORATION, Tokyo (JP)

(21) Appl. No.: 17/751,203

(22) Filed: May 23, 2022

(30) Foreign Application Priority Data
May 28, 2021 (JP) 2021-089903

(51) Int. Cl. H01L 21/324; H01L 21/67

(52) U.S. Cl. CPC H01L 21/324; H01L 21/67115

(57) ABSTRACT

There is provided a technique that include: a process chamber configured to process a substrate at which at least one target film and a heat assist film are formed; and an electromagnetic wave generator configured to supply an electromagnetic wave into the process chamber, wherein when the substrate is irradiated with the electromagnetic wave, the heat assist film generates heat and the at least one target film is modified by the heat.

### CROSS-REFERENCE TO RELATED APPLICATION

This application is based upon and claims the benefit of priority from Japanese Patent Application No. 2021-089903, filed on May 28, 2021, the entire contents of which are incorporated herein by reference.

### TECHNICAL FIELD

The present disclosure relates to a substrate processing apparatus, a method of manufacturing a semiconductor device, and a recording medium.

### BACKGROUND

As a process of manufacturing a semiconductor device, for example, there is modification treatment represented by annealing treatment for heating a substrate in a process chamber by using a heater to change the composition and crystal structure in a thin film formed on the surface of the substrate or repair crystal defects and the like in the filmed thin film. In recent years, semiconductor devices have become remarkably miniaturized and highly integrated, and along with this, there is a demand for modification treatment for a high-density substrate on which a pattern having a high aspect ratio is formed. A heat treatment method using a microwave has been studied as a method for modifying such a high-density substrate.

In the conventional treatment using the microwave, depending on films formed on the substrate, some films may be affected by the thermal history, and it may be difficult to perform desired heat treatment (modification treatment) at a low temperature for a film formed on the substrate while satisfying the thermal history required in a device manufacturing process.

### SUMMARY

Some embodiments of the present disclosure provide a substrate processing apparatus, a method of manufacturing a semiconductor device, and a program, which are capable of modifying a film formed on a substrate while lowering the temperature of the substrate.

According to one embodiment of the present disclosure, there is provided a technique that includes: a process chamber configured to process a substrate at which at least one target film and a heat assist film are formed; and an electromagnetic wave generator configured to supply an electromagnetic wave to the process chamber, wherein when the substrate is irradiated with the electromagnetic wave, the heat assist film generates heat and the at least one target film is modified by the heat.

### BRIEF DESCRIPTION OF DRAWINGS

The accompanying drawings, which are incorporated in and constitute a part of the specification, illustrate embodiments of the present disclosure.

FIG. 1 is a longitudinal sectional view showing a schematic configuration of a substrate processing apparatus suitably used in an embodiment of the present disclosure.

FIG. 2 is a cross-sectional view showing the schematic configuration of the substrate processing apparatus suitably used in the embodiment of the present disclosure.

FIG. 3 is a schematic configuration view of a single-wafer process furnace of the substrate processing apparatus suitably used in the embodiment of the present disclosure, in which a process furnace portion is shown in a longitudinal sectional view.

FIG. 4 is a schematic configuration diagram of a controller of the substrate processing apparatus suitably used in the present disclosure.

FIG. 5 is a diagram showing a flow of substrate processing in the present disclosure.

FIG. 6 is a cross-sectional view showing the configuration of a film on a substrate, which is suitably used in the embodiment of the present disclosure.

FIG. 7 is a diagram showing an example of the refractive index of an amorphous film after modification treatment in the present disclosure.

FIG. 8 is a diagram showing an example of the sheet resistance of the amorphous film after the modification treatment in the present disclosure.

FIG. 9 is a perspective view showing Modification 1 of the configuration of the film on the substrate, which is suitably used in the embodiment of the present disclosure.

FIG. 10 is a cross-sectional view showing Modification 2 of the configuration of the film on the substrate, which is suitably used in the embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to obscure aspects of the various embodiments.

One embodiment of the present disclosure will now be described with reference to the drawings. The drawings used in the following description are schematic, and the dimensional relationship, ratios, and the like of various elements shown in figures do not always match the actual ones. Further, the dimensional relationship, ratios, and the like of various elements between plural figures do not always match each other.

### (1) Configuration of Substrate Processing Apparatus

In the present embodiment, a substrate processing apparatus 100 according to the present disclosure is configured as a single-wafer heat treatment apparatus that performs various heat treatments on a wafer, and will be described with an apparatus that performs annealing treatment (modification treatment) using electromagnetic waves, which will be described later. In the substrate processing apparatus 100 of the present embodiment, a FOUP(Front Opening Unified Pod: hereinafter referred to as a pod) 110 is used as a storage container (carrier) in which a wafer 200 as a substrate is accommodated. The pod 110 is also used as a transfer container for transferring the wafer 200 between various substrate processing apparatuses.

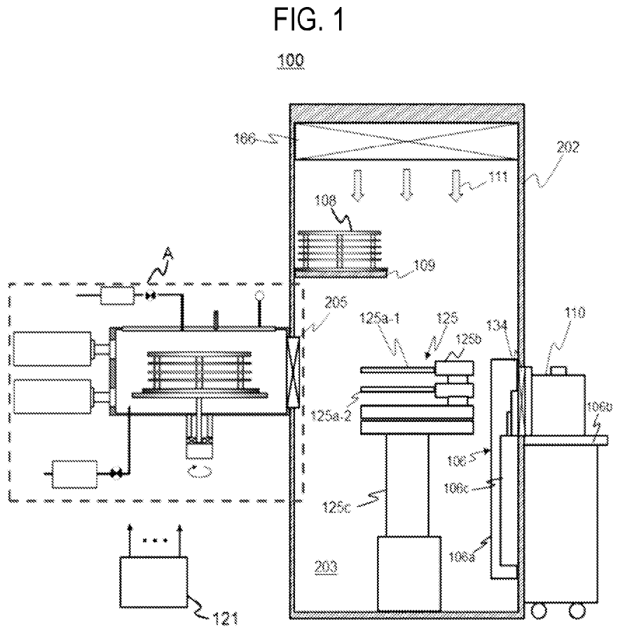

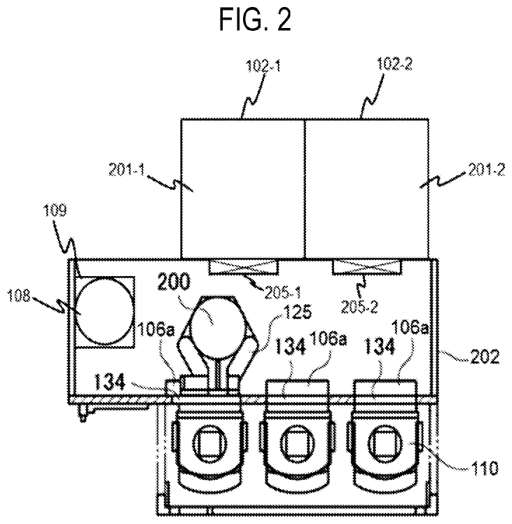

As shown in FIGS. 1 and 2, the substrate processing apparatus 100 includes a transfer housing (housing) 202 having a transfer chamber (transfer area) 203 for transferring the wafer 200, and cases 102-1 and 102-2, which serve as process containers to be described later, that are provided on a side wall of the transfer housing 202 and have process chambers 201-1 and 201-2 for processing the wafer 200, respectively. A load port (LP) 106 as a pod opening/closing mechanism for opening/closing a lid of the pod 110 and loading/unloading the wafer 200 into/from the transfer chamber 203 is arranged on a right side of FIG. 1 (a lower side of FIG. 2) which is a front side of the housing of the transfer chamber 203. The load port 106 includes a housing 106a, a stage 106b, and an opener 106c. The stage 106b mounts the pod 110 and is configured to bring the pod 110 close to a substrate loading/unloading port 134 formed in front of the housing of the transfer chamber 203. The opener 106c opens/closes a lid (not shown) provided on the pod 110. Further, the housing 202 has a purge gas circulation structure provided with a cleaner 166 for circulating a purge gas such as N₂ in the transfer chamber 203.

Gate valves 205-1 and 205-2 that open/close the process chambers 201-1 and 202-2, respectively, are arranged on a left side of FIG. 1 (an upper side of FIG. 2) which is a rear side of the housing 202 of the transfer chamber 203. A transfer machine 125 as a substrate transfer mechanism (substrate transfer robot) for transferring the wafer 200 is installed in the transfer chamber 203. The transfer machine 125 is composed of tweezers (arms) 125a-1 and 125a-2 as mounters for mounting the wafer 200, a transfer device 125b that can rotate or linearly move the tweezers 125a-1 and 125a-2 in a horizontal direction, and a transfer device elevator 125c that raises and lowers the transfer device 125b. By continuous operation of the tweezers 125a-1 and 125a-2, the transfer device 125b, and the transfer device elevator 125c, the wafer 200 can be loaded (charged) or unloaded (discharged) into or from a substrate holder (boat) 217, which will be described later, or the pod 110. Hereinafter, the cases 102-1 and 102-2, the process chambers 201-1 and 201-2, and the tweezers 125a-1 and 125a-2 may be simply referred to as a case 102, a process chamber 201, and tweezers 125a, respectively, if there is no need to distinguish them from each other.

As shown in FIG. 1, in a space above the transfer chamber 203 and below the cleaner 166, a wafer cooling mounting tool 108 for cooling the processed wafer 200 is provided on a wafer cooling table 109. The wafer cooling mounting tool 108 has a structure similar to that of the boat 217 as the substrate holder to be described later and is configured to be capable of holding a plurality of wafers 200 horizontally in multiple vertical stages by a plurality of wafer holding grooves (holding portions). By providing the wafer cooling mounting tool 108 and the wafer cooling table 109 above the installation positions of the substrate loading/unloading port 134 and the gate valve 205, they are out of deviates from a line of flow when the wafer 200 is transferred from the pod 110 to the process chamber 201 by the transfer machine 125, thereby making it possible to cool the processed wafer 200 without lowering the wafer processing throughput. Hereinafter, the wafer cooling mounting tool 108 and the wafer cooling table 109 may be collectively referred to as a cooling area.

Here, an internal pressure of the pod 110, an internal pressure of the transfer chamber 203, and an internal pressure of the process chamber 201 are controlled to be the atmospheric pressure or a pressure higher by about 10 to 200 Pa (gauge pressure) than the atmospheric pressure. It is preferable that the internal pressure of the transfer chamber 203 is higher than the internal pressure of the process chamber 201 and the internal pressure of the process chamber 201 is higher than the internal pressure of the pod 110.

### (Process Furnace)

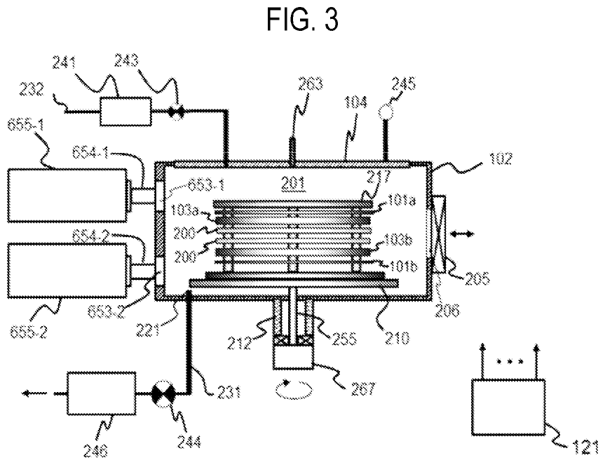

A process furnace having a substrate processing structure as shown in FIG. 3 is configured in a region A surrounded by a broken line in FIG. 1. In the present embodiment, a plurality of process furnaces are provided as shown in FIG. 2, but since the configurations of the process furnaces are the same, one configuration will be described and the description of the other process furnace configuration will be omitted.

As shown in FIG. 3, the process furnace has the case 102 as a cavity (process container) made of a material that reflects electromagnetic waves, such as metal. Further, on a ceiling surface of the case 102, a cap flange (closing plate) 104 made of a metal material is configured to close the ceiling surface of the case 102 via an O-ring (not shown) as a seal. An inner space of the case 102 and the cap flange 104 is mainly configured as the process chamber 201 for processing a substrate such as a silicon wafer. A reaction tube (not shown) made of quartz that allows electromagnetic waves to pass through may be installed inside the case 102, or a process container may be configured so that an interior of the reaction tube serves as a process chamber. Further, the process chamber 201 may be configured by using the case 102 having a closed ceiling without providing the cap flange 104.

A mounting table 210 is provided in the process chamber 201, and the boat 217 as the substrate holder for holding the wafer 200 as the substrate is mounted on the upper surface of the mounting table 210. The boat 217 holds the wafer 200 to be processed and quartz plates 101a and 101b as heat insulating plates placed vertically above and below the wafer 200 so as to sandwich the wafer 200 at predetermined intervals. Further, susceptors 103a and 103b such as a silicon plate (Si plate) and a silicon carbide plate (SiC plate) may be placed between the quartz plates 101a and 101b and the wafer 200, respectively. In the present embodiment, the quartz plates 101a and 101b and the susceptors 103a and 103b are the same parts, respectively, and if there is no need to distinguish them from each other, they will be referred to as a quartz plate 101 and a susceptor 103.

The case 102 as the process container has, for example, a circular cross section and is configured as a flat closed container. Further, the transfer housing 202 is made of, for example, a metal material such as aluminum (Al) or stainless steel (SUS). A space surrounded by the case 102 may be referred to as the process chamber 201 or a reaction area 201 as a process space, and a space surrounded by the transfer housing 202 may be referred to as the transfer chamber 203 or the transfer area 203 as a transfer space. The process chamber 201 and the transfer chamber 203 are not limited to be configured to be adjacent to each other in the horizontal direction as in the present embodiment, but may be configured to be adjacent to each other in the vertical direction.

As shown in FIGS. 1, 2, and 3, a substrate loading/unloading port 206 adjacent to the gate valve 205 is provided on the side surface of the transfer housing 202, and the wafer 200 moves between the process chamber 201 and the transfer chamber 203 through the substrate loading/unloading port 206.

An electromagnetic wave supplier as a heater, which will be described in detail later, is installed on the side surface of the case 102, and an electromagnetic wave such as a microwave supplied from the electromagnetic wave supplier is introduced to the process chamber 201 to process the wafer 200 by heating the wafer 200 and the like.

The mounting table 210 is supported by a shaft 255 as a rotary shaft. The shaft 255 penetrates the bottom of the case 102 and is further connected to a drive mechanism 267 that performs the rotation operation outside the transfer housing 202. By operating the drive mechanism 267 to rotate the shaft 255 and the mounting table 210, it is possible to rotate the wafer 200 placed on the boat 217. Further, the circumference of the lower end portion of the shaft 255 is covered with a bellows 212 to keep the inside of the process chamber 201 and the transfer area 203 airtight.

Here, the mounting table 210 may be configured to be raised or lowered according to a height of the substrate loading/unloading port 206 by the drive mechanism 267 so that the wafer 200 is at a wafer transfer position when the wafer 200 is transferred, and to be raised or lowered to a processing position (wafer processing position) in the process chamber 201 when the wafer 200 is processed.

An exhauster for exhausting the atmosphere of the process chamber 201 is provided below the process chamber 201 and on the outer peripheral side of the mounting table 210. As shown in FIG. 3, an exhaust port 221 is provided in the exhauster. An exhaust pipe 231 is connected to the exhaust port 221, and a pressure regulator 244 such as an APC valve that controls the valve opening according to the internal pressure of the process chamber 201 and a vacuum pump 246 are sequentially connected in series to the exhaust pipe 231.

Here, the pressure regulator 244 is not limited to the APC valve as long as it can receive pressure information (a feedback signal from a pressure sensor 245 to be described later) in the process chamber 201 and adjust the exhaust amount, but may be configured to be used together with the normal opening/closing and pressure regulating valve.

The exhauster (also referred to as an exhaust system or an exhaust line) mainly includes the exhaust port 221, the exhaust pipe 231, and the pressure regulator 244. The exhaust port may be provided so as to surround the mounting table 210 so that a gas can be exhausted from the entire circumference of the wafer 200. Further, the vacuum pump 246 may be added to the configuration of the exhauster.

The cap flange 104 is provided with a gas supply pipe 232 for supplying process gases for processing various substrates, such as an inert gas, a precursor gas, and a reaction gas, into the process chamber 201.

The gas supply pipe 232 is provided with a mass flow controller (MFC) 241, which is a flow rate controller (flow rate control part), and a valve 243, which is an opening/closing valve, sequentially from the upstream. For example, an inert gas source is connected to the upstream side of the gas supply pipe 232 to supply an inert gas into the process chamber 201 via the MFC 241 and the valve 243. When a plurality of types of gases are used for substrate processing, the plurality of types of gases can be supplied by using a configuration in which a gas supply pipe provided with a MFC, which is a flow rate controller, and a valve, which is an opening/closing valve, sequentially from the upstream side is connected to the downstream side of the valve 243 of the gas supply pipe 232. Further, a gas supply pipe provided with an MFC and a valve may be installed for each gas type.

A gas supply system (gas supplier) mainly includes the gas supply pipe 232, the MFC 241, and the valve 243. When an inert gas is flowed into the gas supply system, the gas supply system is also referred to as an inert gas supply system. As the inert gas, for example, a N₂ gas or a rare gas such as an Ar gas, a He gas, a Ne gas, or a Xe gas can be used.

A temperature sensor 263, which is a non-contact temperature measuring device, is installed on the cap flange 104. By adjusting the output of a microwave oscillator 655, which will be described later, based on temperature information detected by the temperature sensor 263, the substrate is heated so that the substrate temperature has a desired temperature distribution. The temperature sensor 263 is composed of a radiation thermometer such as an IR (Infrared Radiation) sensor. The temperature sensor 263 is installed so as to measure the surface temperature of the quartz plate 101a or the surface temperature of the wafer 200. If the above-mentioned susceptor is provided, the temperature sensor 263 may be configured to measure the surface temperature of the susceptor.

When the temperature of the wafer 200 (wafer temperature) is described in the present disclosure, it will be described as referring to as a case where it means a wafer temperature converted by temperature conversion data to be described later, that is, an estimated wafer temperature, a case where it means a temperature obtained by directly measuring the temperature of the wafer 200 with the temperature sensor 263, and a case where it means both of them.

By acquiring the transition of the temperature change for each of the quartz plate 101 or the susceptor 103 and the wafer 200 in advance by the temperature sensor 263, the temperature conversion data showing the correlation between the temperature of the quartz plate 101 or the susceptor 103 and the temperature of the wafer 200 may be stored in a memory 121c or an external memory 123. By creating the temperature conversion data in advance in this way, the temperature of the wafer 200 can be estimated by measuring the temperature of the quartz plate 101, and the output of the microwave oscillator 655, that is, the heater, can be controlled based on the estimated temperature of the wafer 200.

A means for measuring the temperature of the substrate is not limited to the above-mentioned radiation thermometer. The temperature of the substrate may be measured using a thermocouple or a combination of a thermocouple and a non-contact thermometer. However, when the temperature of the substrate is measured using the thermocouple, the thermocouple should be arrange in the vicinity of the wafer 200 to measure the temperature. That is, since the thermocouple should be arrange in the process chamber 201, the thermocouple itself is heated by the microwave supplied from the microwave oscillator to be described later, so that the temperature cannot be accurately measured. Therefore, it is preferable to use a non-contact thermometer as the temperature sensor 263.

Further, the temperature sensor 263 is not limited to being provided on the cap flange 104, but may be provided on the mounting table 210. Further, the temperature sensor 263 is not only directly installed on the cap flange 104 or the mounting table 210, but also may be configured to indirectly measure the temperature by reflecting radiated light from a measurement window provided on the cap flange 104 or the mounting table 210 with a mirror or the like. Further, the number of temperature sensors 263 is not limited to one, and a plurality of temperature sensors 263 may be installed.

Electromagnetic wave introduction ports 653-1 and 653-2 are installed on the side wall of the case 102. One ends of waveguides 654-1 and 654-2 for supplying an electromagnetic wave into the process chamber 201 are connected to the electromagnetic wave introduction ports 653-1 and 653-2, respectively. Microwave oscillators (electromagnetic wave sources or electromagnetic wave oscillators) 655-1 and 655-2 as heating sources for supplying electromagnetic waves into the process chamber 201 to heat the wafer 200 are connected to the other ends of the waveguides 654-1 and 654-2, respectively. The microwave oscillators 655-1 and 655-2 supply the electromagnetic waves such as microwaves to the waveguides 654-1 and 654-2, respectively. A magnetron, a klystrons, and the like are used as the microwave oscillators 655-1 and 655-2. Hereinafter, the electromagnetic wave introduction ports 653-1 and 653-2, the waveguides 654-1 and 654-2, and the microwave oscillators 655-1 and 655-2 will be described as an electromagnetic wave introduction port 653, a waveguide 654, and a microwave oscillator 655, respectively, if there is no need to distinguish them from each other.

The frequency of an electromagnetic wave generated by the microwave oscillator 655 is preferably controlled to fall with a frequency range of 13.56 MHz or more and 24.125 GHz or less. More suitably, the frequency is preferably controlled to 2.45 GHz or 5.8 GHz. Here, the frequencies of the microwave oscillators 655-1 and 655-2 may be the same frequency or may be different frequencies.

Further, it is described in the present embodiment that two microwave oscillators 655 are arranged on the side surface of the case 102, but the present disclosure is not limited thereto. For example, one or more microwave oscillators may be arranged on different side surfaces such as the opposite side surfaces of the case 102. The electromagnetic wave supplier (also referred to as an electromagnetic wave supply device, a microwave supplier, or a microwave supply device) as a heater mainly includes the microwave oscillators 655-1 and 655-2, the waveguides 654-1 and 654-2, and the electromagnetic wave introduction ports 653-1 and 653-2.

A controller 121, which will be described later, is connected to each of the microwave oscillators 655-1 and 655-2. The temperature sensor 263 for measuring the temperature of the quartz plate 101a or 101b or the wafer 200 accommodated in the process chamber 201 is connected to the controller 121. The temperature sensor 263 measures the temperature of the quartz plate 101, the susceptor 103, or the wafer 200 by the above-described method and transmits the measured temperature to the controller 121, and the controller 121 controls the outputs of the microwave oscillators 655-1 and 655-2 to control the heating of the wafer 200.

Here, the microwave oscillators 655-1 and 655-2 are controlled by the same control signal transmitted from the controller 121. However, the present disclosure is not limited thereto. For example, the microwave oscillators 655-1 and 655-2 may be individually controlled by transmitting individual control signals from the controller 121 to the microwave oscillators 655-1 and 655-2, respectively.

### (Controller)

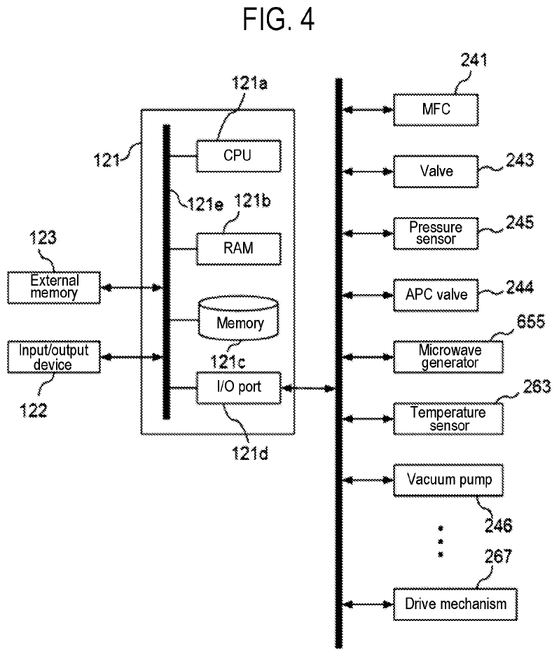

As shown in FIG. 4, the controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, e.g., a touch panel or the like, is connected to the controller 121.

The memory 121c is configured by, for example, a flash memory, a hard disk drive (HDD), or the like. A control program for controlling operations of a substrate processing apparatus, a process recipe in which sequences and conditions of annealing (modification) treatment are written, etc. are readably stored in the memory 121c. The process recipe functions as a program for causing the controller 121 to execute each sequence in the substrate processing process, which will be described later, to obtain an expected result. Hereinafter, the process recipe and the control program may be generally and simply referred to as a “program.” Furthermore, the process recipe may be simply referred to as a “recipe.” When the term “program” is used herein, it may indicate a case of including the recipe, a case of including the control program, or a case of including both the recipe and the control program. The RAM 121b is configured as a memory area (work area) in which programs or data read by the CPU 121a are temporarily stored.

The I/O port 121d is connected to the MFC 241, the valve 243, the pressure sensor 245, the APC valve 244, the vacuum pump 246, the temperature sensor 263, the drive mechanism 267, the microwave oscillator 655, and so on.

The CPU 121a is configured to read and execute the control program from the memory 121c. The CPU 121a is also configured to read the recipe from the memory 121c according to an input of an operation command from the input/output device 122. The CPU 121a is configured to control the flow rate adjusting operation of various kinds of gases by the MFC 241, the opening/closing operation of the valve 243, the pressure adjusting operation performed by the APC valve 244 based on the pressure sensor 245, the actuating and stopping operation of the vacuum pump 246, the output adjusting operation performed by the microwave oscillator 655 based on the temperature sensor 263, the operation of rotating the mounting table 210 (or the boat 217) and adjusting the rotation speed of the mounting table 210 with the drive mechanism 267 or the operation of raising/lowering the mounting table 210, and so on, according to contents of the read recipe.

The controller 121 may be configured by installing, on the computer, the aforementioned program stored in the external memory (for example, a magnetic disk such as a hard disk, an optical disc such as a CD, a magneto-optical disc such as a MO, or a semiconductor memory such as a USB memory or a SSD) 123. The memory 121c or the external memory 123 is configured as a non-transitory computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Furthermore, the program may be provided to the computer by using communication means such as the Internet or a dedicated line, instead of using the external memory 123.

### (2) Substrate Processing Process

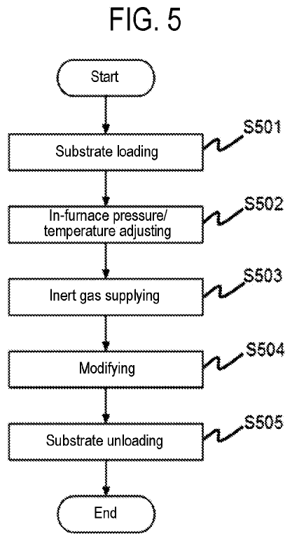

Next, using the process furnace of the above-described substrate processing apparatus 100, as a process of manufacturing a semiconductor device, an example of a method of modifying (crystallizing) an amorphous silicon (Si) film containing phosphorus (P) (a silicon film added (doped) with P, P-doped-Si film, or P-containing silicon film) 2002, for example, as a film (treatment object film or target film), which is the object of heat treatment (modification treatment), formed on the substrate 200 will be described along with a process flow shown in FIG. 5.

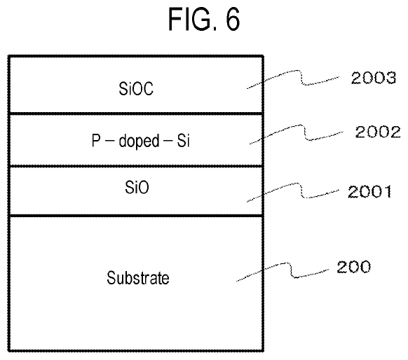

As shown in FIG. 6, a silicon oxide film (SiO film) 2001 and a P-doped-Si film 2002, which is the target film, are formed on the substrate 200. Further, as a film (heat assist film or action object film) that assists heating of a film (treatment object film or target film) which is the object of this heat treatment (modification treatment), a silicon oxide film (SiOC film) 2003 containing carbon (C) is formed on the surface of this P-doped-Si film 2002. That is, the SiOC film 2003 is formed adjacent to the P-doped-Si film 2002.

The SiO film 2001 is a film formed by diffusing oxygen (O) on the surface of a silicon substrate with an oxygen atmosphere set in a reaction chamber having a predetermined temperature (for example, 900 degrees C.). Further, the P-doped-Si film 2002 is a film formed by supplying, for example, SiH₄ (monosilane) and PH₃ (phosphine) into the reaction chamber having a predetermined temperature (for example, 500 degrees C. to 650 degrees C.). Further, the SiOC film 2003 is a film formed by supplying a precursor gas into the reaction chamber having a predetermined temperature (for example, 300 degrees C.). These SiO film 2001, P-doped-Si film 2002, and SiOC film 2003 are formed on the substrate 200 in a substrate processing apparatus different from the above-described substrate processing apparatus 100, for example, by a batch type substrate processing apparatus.

In the following description, the operation of each part constituting the substrate processing apparatus 100 is controlled by the controller 121. Further, as in the above-described process furnace structure, since the same recipe is used in a plurality of process furnaces provided for the processing contents, that is, the recipes, in the substrate processing process in the present embodiment, a substrate processing process using one of the process furnaces will be described, and the description of the substrate processing process using the other process furnace will be omitted.

When the term “wafer” is used in the present disclosure, it may refer to “a wafer itself” or “a wafer and a stacked body of certain layers or films formed on a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

### (Substrate Loading Step (S501))

As shown in FIG. 3, the wafer 200 placed on one or both of the tweezers 125a-1 and 125a-2 is loaded into a predetermined process chamber 201 by the opening/closing operation of the gate valve 205 (S501).

### (In-Furnace Pressure/Temperature Adjusting Step (S502))

When the loading of the wafer 200 into the process chamber 201 is completed, the internal atmosphere of the process chamber 201 is controlled so that the internal pressure of the process chamber 201 becomes a predetermined pressure (for example, 10 to 102,000 Pa). Specifically, while exhausting an interior of the process chamber 201 by the vacuum pump 246, the valve opening degree of the pressure regulator 244 is feedback-controlled based on the pressure information detected by the pressure sensor 245, so that the interior of the process chamber 201 is set to the predetermined pressure. At the same time, the electromagnetic wave supplier may be controlled with preheating to control the heating to a predetermined temperature (S502). When the temperature is raised to a predetermined substrate processing temperature by the electromagnetic wave supplier, it is preferable to raise the temperature with an output smaller than the output of a modifying step, which will be described later, so that the wafer 200 is not deformed or damaged. Further, when the substrate processing is performed under the atmospheric pressure, the process may be controlled so as to proceed to an inert gas supplying step S503, which will be described later, after adjusting the in-furnace temperature without adjusting the in-furnace pressure.

### (Inert Gas Supplying Step (S503))

When the internal pressure and temperature of the process chamber 201 are controlled to predetermined values by the in-furnace pressure/temperature adjusting step S502, the drive mechanism 267 rotates the shaft 255 to rotate the wafer 200 via the boat 217 on the mounting table 210. At this time, an inert gas such as a nitrogen gas is supplied via the gas supply pipe 232 (S503). Further, at this time, the internal pressure of the process chamber 201 is a predetermined value in a range of 10 Pa or more and 102,000 Pa or less and is adjusted to be, for example, 101,300 Pa or more and 101,650 Pa or less. The shaft may be rotated during the substrate loading step S501, that is, after the wafer 200 is loaded into the process chamber 201.

### (Modifying Step (S504))

When the interior of the process chamber 201 is maintained at the predetermined pressure, the microwave oscillator 655 supplies a microwave into the process chamber 201 for a predetermined time (heating time or processing time), for example, for 600 seconds, via the above-described parts. When an electromagnetic wave such as a microwave is supplied into the process chamber 201, the C-containing silicon oxide film (SiOC film) 2003 as a heat assist film (action object film) is irradiated with the microwave, so that the C-containing silicon oxide film (SiOC film) 2003 is heated. Due to the heat generation of the C-containing silicon oxide film, the silicon film added (doped) with P(P-doped-Si film) 2002 as an adjacent target film (treatment object film) is heated and modified (crystallized).

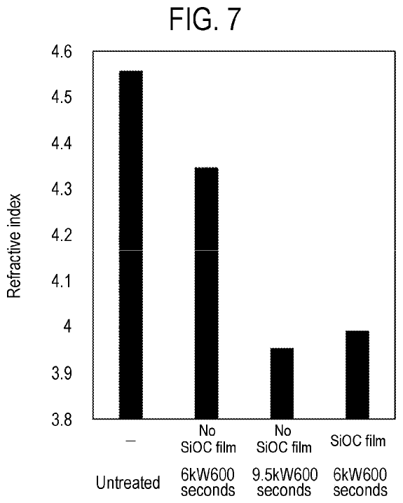

FIG. 7 shows the refractive index of the silicon film added (doped) with P (the amorphous silicon film, P-doped-Si film, treatment object film, or target film) 2002 after modification treatment (annealing treatment) by the microwave. The refractive index of the P-doped-Si film 2002 is about 4.5 when untreated, indicating that the P-doped-Si film 2002 is amorphous. When the modification treatment is performed at the microwave output of 6.0 kW for 600 seconds without the SiOC film 2003, the refractive index of the P-doped-Si film 2002 is about 4.3, indicating that the P-doped-Si film 2002 is insufficiently crystallized. When the modification treatment is performed at the microwave output of 9.5 kW for 600 seconds without the SiOC film (action object film or heat assist film) 2003, the refractive index of the P-doped-Si film 2002 is about 4.0, indicating that the P-doped-Si film 2002 is crystallized. When the SiOC film 2003 is formed on the P-doped-Si film 2002 and the modification treatment is performed at the microwave output of 6.0 kW for 600 seconds, the refractive index of the P-doped-Si film 2002 is about 4.0, indicating that the P-doped-Si film 2002 is crystallized. This indicates that when the SiOC film 2003 is irradiated with the microwave, the SiOC film 2003 is heated and generates heat and the adjacent P-doped-Si film 2002 is heated and crystallized. That is, when the SiOC film 2003 is formed adjacent to the P-doped-Si film 2002 and the modification treatment is performed, the modification treatment can be performed with the reduced microwave output. Further, since the microwave output can be reduced, the P-doped-Si film (treatment object film or target film) 2002 can be modified at a lower temperature. Therefore, since the target film such as the P-doped-Si film 2002 can be modified at a low temperature, it is possible to perform the modification treatment while suppressing the influence of the thermal history.

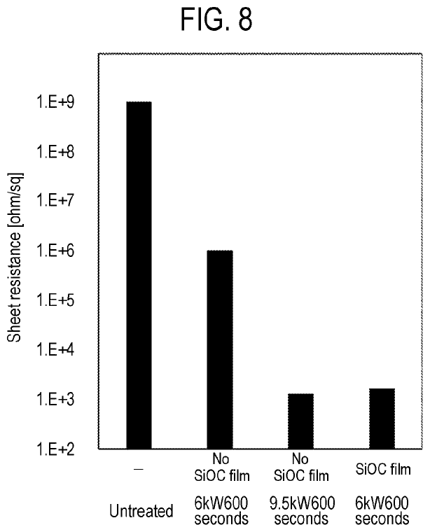

FIG. 8 shows the sheet resistance of the silicon film added (doped) with P (the amorphous silicon film or P-doped-Si film) 2002 after modification treatment (annealing treatment) by the microwave. The sheet resistance of the P-doped-Si film 2002 is about 1e9 ohm/sq (1. E+9 ohm/sq) when untreated, indicating that the P-doped-Si film 2002 is amorphous. When the modification treatment is performed at the microwave output of 6.0 kW for 600 seconds without the SiOC film 2003, the sheet resistance of the P-doped-Si film 2002 is about 1e6 ohm/sq (1. E+6 ohm/sq), indicating that the P-doped-Si film 2002 is insufficiently activated. When the modification treatment is performed at the microwave output of 9.5 kW for 600 seconds without the SiOC film 2003, the sheet resistance of the P-doped-Si film 2002 is about 1e3 ohm/sq (1. E+3 ohm/sq), indicating that the P-doped-Si film 2002 is activated. When the SiOC film 2003 is formed on the P-doped-Si film 2002 and the modification treatment is performed at the microwave output of 6.0 kW for 600 seconds, the sheet resistance of the P-doped-Si film 2002 is about 1e3 ohm/sq (1. E+3 ohm/sq), indicating that the P-doped-Si film 2002 is activated. This indicates that the P-doped-Si film 2002 is sufficiently activated with substantially the same sheet resistance as when the modification treatment is performed at the microwave output of 9.5 kW for 600 seconds without the SiOC film 2003. As a result, this indicates that by irradiating the SiOC film 2003 with the microwave, the SiOC film (action object film or heat assist film) 2003 is heated and generates heat and the adjacent P-doped-Si film (treatment object film or target film) 2002 is heated and activated. That is, when the SiOC film 2003 is formed adjacent to the P-doped-Si film 2002 and the modification treatment is performed, the modification treatment can be performed with the reduced microwave output. Further, since the microwave output can be reduced, the P-doped-Si film (target film) 2002 can be modified at a lower temperature. Therefore, since the target film such as the P-doped-Si film 2002 can be modified at a low temperature, it is possible to perform the modification treatment while suppressing the influence of the thermal history.

After the preset processing time elapses, the rotation of the boat 217, the supply of the gas, the supply of the microwave, and the exhaust of the exhaust pipe are stopped.

### (Substrate Unloading Step (S505))

After the internal pressure of the process chamber 201 is returned to the atmospheric pressure, the gate valve 205 is opened to spatially communicate the process chamber 201 with the transfer chamber 203. After that, the wafer 200 placed on the boat is unloaded to the transfer chamber 203 by the tweezers 125a of the transfer machine 125 (S505).

By repeating the above operation, the wafer 200 is modified and the process proceeds to the next substrate processing process.

As the next substrate processing process, for example, if the above-mentioned SiOC film (action object film or heat assist film) 2003 is an unnecessary film due to the device characteristics, a step of removing the SiOC film should be performed. If the heat assist film is useful due to the device characteristics, the heat assist film may not be removed.

In the present disclosure, it is preferable that the microwave absorption rate of the heat assist film 2003 is larger than that of other films (for example, the SiO film 2001) on the substrate 200 excluding the substrate 200 and the target film 2002, and the larger the difference thereof, the more the thermal history of other film (for example, the SiO film 2001) can be suppressed.

Equation 1 is an equation showing the amount of energy by dielectric heating. As a substance having a large absorption rate of microwave, in the case of heating by dielectric heating, a substance having εᵣ (relative permittivity of dielectric) and tan δ (dielectric loss angle of dielectric) sufficiently larger than the absorption rate of microwave of, for example, a silicon substrate (Si substrate) may be contained in the above-mentioned heat assist film.

P₁=K·εᵣ·tan δ·f·E² [Eq. 1]
K: 0.556×10⁻¹⁰
εᵣ: relative permittivity of dielectric
tan δ: dielectric loss angle of dielectric
f: frequency [Hz]
E: electric field intensity [V/m]

Further, in the case of heating using Joule heat, it is possible to heat a metal thin film such as Ti (titanium), TiN (titanium nitride), Ni (nickel), or Co (cobalt) by the fine wire effect.

Although the above description has been made using the microwave, since the absorption characteristics of a substance contained in the heat assist film also depend on the wavelength of an electromagnetic wave, the present disclosure can employ wavelengths of various electromagnetic waves other than the microwave.

### Effects of the Present Embodiment

According to the present embodiment, one or more effects set forth below can be obtained.

(a) When the P-doped-Si film (target film) 2002 is modified (heat-treated), it possible to reduce the output of the irradiated microwave by the SiOC film (heat assist film) 2003.

(b) When the P-doped-Si film 2002 is modified, since it possible to reduce the output of the irradiated microwave by the SiOC film (heat assist film) 2003, it possible to modify the P-doped-Si film (target film) 2002 at a lower temperature.

(c) Since the target film such as the P-doped-Si film 2002 can be modified at a low temperature, it is possible to perform the modification treatment while suppressing the influence of the thermal history.

### (Modification 1)

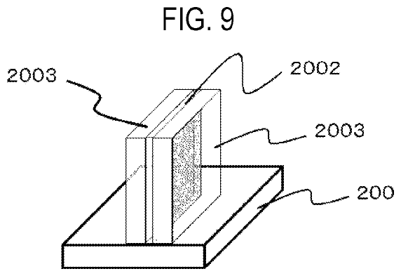

Hereinafter, Modification 1 of the present embodiment will be described. As shown in FIG. 9, in Modification 1, two heat assist films 2003 are formed adjacent to each other so as to sandwich the target film 2002 formed on the substrate 200. By forming the heat assist films 2003 in this way, it is possible to efficiently heat the target film from both sides. Further, by adjusting the film thicknesses of the two heat assist films 2003, it is possible to adjust the heating amount for the target film 2002.

### (Modification 2)

Hereinafter, Modification 2 of the present embodiment will be described.

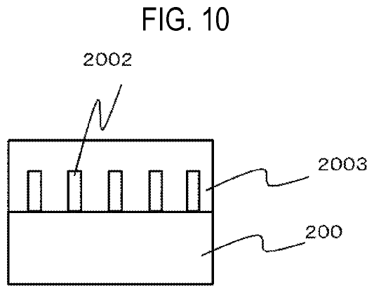

As shown in FIG. 10, in Modification 2, a heat assist film 2003 is formed to cover (surround) a plurality of target films 2002 (five target films 2002 in Modification 2) formed adjacent to each other on the substrate 200. By forming the heat assist film in this way, it is possible to efficiently heat groove portions between the plurality of target films 2002 and the upper portion of the target film. Further, by adjusting the film thickness of the upper portion of the heat assist film, it is possible to adjust the heating amount for the target films 2002.

As described above, according to the present disclosure, it is possible to provide a technique for modifying a film formed on a substrate while lowering the temperature of the substrate.

According to the present disclosure in some embodiments, it is possible to provide a configuration capable of modifying a film formed on a substrate while lowering the temperature of the substrate.

While certain embodiments have been described, these embodiments have been presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the disclosures. The accompanying claims and their equivalents are intended to cover such forms or modifications as would fall within the scope of the disclosures.

What is claimed is:

1. A substrate processing apparatus comprising:
a process chamber configured to process a substrate at which at least one target film and a heat assist film are formed; and
an electromagnetic wave generator configured to supply an electromagnetic wave to the process chamber,
wherein when the substrate is irradiated with the electromagnetic wave, the heat assist film generates heat and the at least one target film is modified by the heat.

2. The substrate processing apparatus of claim 1, wherein the heat assist film is provided on a surface of the at least one target film.

3. The substrate processing apparatus of claim 1, wherein the heat assist film is provided adjacent to the at least one target film.

4. The substrate processing apparatus of claim 1, wherein the heat assist film is provided on both sides of the at least one target film.

5. The substrate processing apparatus of claim 1, wherein the at least one target film includes a plurality of target films,
wherein the plurality of target films are formed on the substrate, and
wherein the heat assist film is provided so as to cover the plurality of target films.

6. The substrate processing apparatus of claim 1, wherein the at least one target film is a silicon film added with phosphorus.

7. The substrate processing apparatus of claim 6, wherein the heat assist film is a carbon-containing silicon oxide film.

8. The substrate processing apparatus of claim 7, wherein when the substrate is irradiated with the electromagnetic wave, the carbon-containing silicon oxide film generates heat and the silicon film added with phosphorus is heated and crystallized by the heat.

9. The substrate processing apparatus of claim 1, wherein the heat assist film is removed after the modification is completed.

10. The substrate processing apparatus of claim 1, wherein the electromagnetic wave is a microwave.

11. The substrate processing apparatus of claim 10, wherein the heat assist film contains a substance having a microwave absorption rate larger than a microwave absorption rate of the substrate.

12. A method of manufacturing a semiconductor device in a substrate processing apparatus including a process chamber configured to process a substrate at which at least one target film and a heat assist film are formed, and an electromagnetic wave generator configured to supply an electromagnetic wave to the process chamber, wherein when the substrate is irradiated with the electromagnetic wave, the heat assist film generates heat and the at least one target film is modified by the heat, the method comprising:
loading the substrate to the process chamber;
supplying the electromagnetic wave to the substrate; and
modifying the at least one target film.

13. The method of claim 12, wherein the heat assist film is removed after the act of modifying the at least one target film.

14. A non-transitory computer-readable recording medium storing a program that causes, by a computer, a substrate processing apparatus including a process chamber configured to process a substrate at which at least one target film and a heat assist film are formed, and an electromagnetic wave generator configured to supply an electromagnetic wave to the process chamber, wherein when the substrate is irradiated with the electromagnetic wave, the heat assist film generates heat and the at least one target film is modified by the heat, to perform a process comprising:
loading the substrate to the process chamber;
supplying the electromagnetic wave to the substrate; and
modifying the at least one target film.

15. The non-transitory computer-readable recording medium of claim 14, wherein the heat assist film is removed after the act of modifying the at least one target film.
